(19) United States
(12) Patent Application Publication
(10) Pub. No.: US 2012/0063111 A1
(43) Pub. Date: Mar. 15, 2012

(54) ELECTRICAL OUTLET BOX

(76) Inventor: Albert STEKELENBURG, Taipei (TW)

(21) Appl. No.: 12/882,914

(22) Filed: Sep. 15, 2010

(51) Int. Cl. H05K 7/00

(52) U.S. Cl. 361/807

(57) ABSTRACT

An electrical outlet box includes a housing comprising a plurality of electrical components and a switch; a cover adapted to close onto the housing and comprising an opening above the switch; and at least one manipulation assembly each disposed between the opening of the cover and the switch, each manipulation assembly comprising a membrane member mounted on the opening of the cover, and a lever block so that a pressing of the membrane member can turn on or off the switch via the lever block.

### BACKGROUND OF THE INVENTION

1. Field of Invention

The invention relates to electrical outlet boxes and more particularly to such an electrical outlet box for sealingly containing electrical components and a switch which can be open or closed by pressing a membrane member on the cover via an intermediate lever block urged against the switch.

2. Description of Related Art

A typical electrical outlet box is shown in FIG. 1 is shown in FIG. 1 and comprises a housing A and a cover B. Electrical components C and a switch D are contained in the housing A. The cover B is mounted on the housing A for sealing. A plurality of openings E are provided on peripheral walls of the housing A for wiring passing. A timer or an on/off operation of the switch D can activate the timer which in turn activates the electrical components C for action in predetermined time. An individual may open the cover B to turn on or if the switch D.

Rain, snow, moisture, etc. may enter the housing A if the electrical outlet box is mounted outdoors. Further, cover opening and switch pressing may have difficulties or even cause danger in cold weather. Thus, the need for improvement still exists.

### SUMMARY OF THE INVENTION

It is therefore one object of the invention to provide an electrical outlet box having a switch which can be open or closed by pressing the cover without opening the electrical outlet box.

It is another object of the invention to provide an electrical outlet box having electrical components in the housing being protected from being damaged due to rain, snow, etc. entering.

It is a further object of the invention to provide an electrical outlet box having a separator plate on the switch so that only required components for pressing are exposed with others being concealed by the separator plate.

To achieve the above and other objects, the invention provides an electrical outlet box comprising a housing comprising a plurality of electrical components and a switch;

a cover adapted to close onto the housing and comprising an opening above the switch; and at least one manipulation assembly each disposed between the opening of the cover and the switch, each manipulation assembly comprising a membrane member mounted on the opening of the cover, and a lever block so that a pressing of the membrane member can turn on or off the switch via the lever block.

The above and other objects, features and advantages of the invention will become apparent from the following detailed description taken with the accompanying drawings.

### BRIEF DESCRIPTION OF THE DRAWINGS

FIG. 1 is an exploded perspective view of a typical electrical outlet box;

FIG. 2 is an exploded perspective view of an electrical outlet box according to the invention;

FIG. 3 is a top plan view of the assembled electrical outlet box of FIG. 2; and

FIGS. 4A, 4B and 4C are sectional views taken along line A-A of FIG. 3 for showing first, second, and third operations of the manipulation assembly respectively.

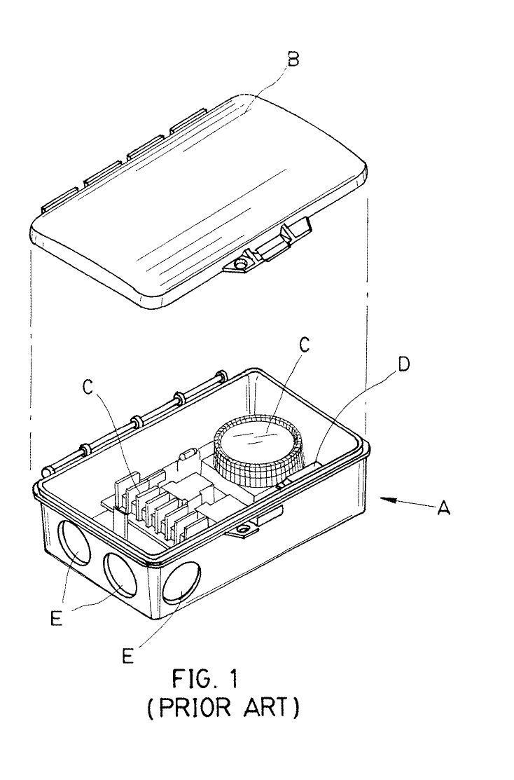

### DETAILED DESCRIPTION OF THE INVENTION

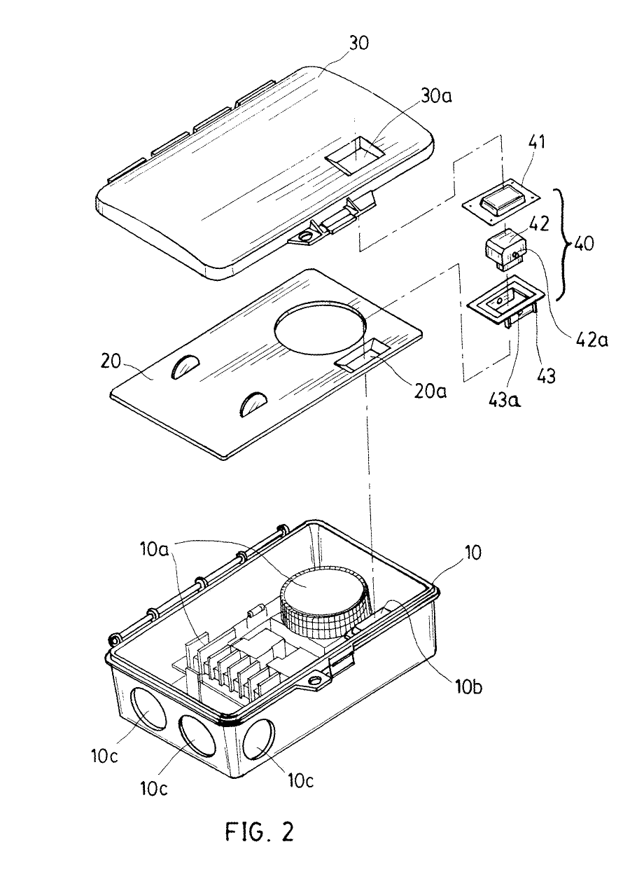

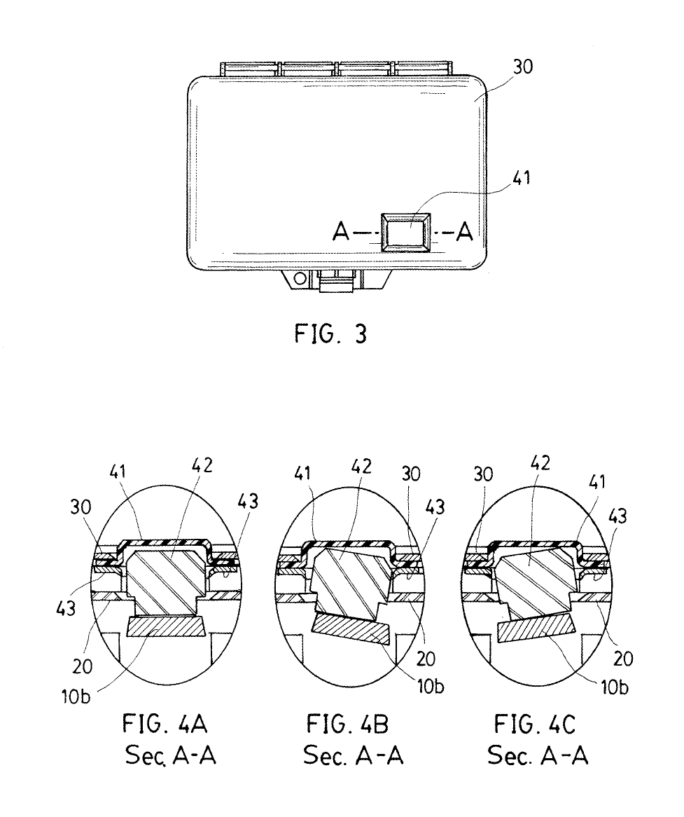

Referring to FIGS. 2 to 4C, an electrical outlet box in accordance with a preferred embodiment of the invention comprises the following components as discussed in detail below.

A hollow, rectangular housing 10 is provided with electrical components 10a, a switch 10b, and a plurality of openings 10c on peripheral walls of the housing 10 for wiring passing.

A rectangular separator plate 20 comprises a rectangular opening 20a. The separator plate 20 is fitted in the housing 10 to cover most components of the electrical components 10a except a number of components which are required to be exposed. The opening 20a is aligned with the switch 10b therebelow.

A rectangular cover 30 comprises a rectangular opening 30a. The cover 30 is secured onto the housing 10 to conceal the separator plate 20 in the housing 10 with the opening 30a being aligned with the opening 20a therebelow.

A manipulation assembly 40 is mounted in the openings 30a, 20a with its bottom urged against the switch 10b as detailed below. The manipulation assembly 40 comprises a top membrane member 41, a lever block 42, and a lower frame 43. The membrane member 41 is sealingly mounted on the opening 30a for preventing water from entering the housing 10 through the opening 30a. The membrane member 41 is flexible in nature so that an individual may press the membrane member 41 to manipulate the lever block 42. The frame 43 is mounted under the opening 30a but above the opening 20a. The lever block 42 is pivotably disposed in the frame 43 as detailed below. The frame 43 comprises two opposite pivot holes 43a. The lever block 42 comprises two opposite pivot pins 42a disposed in the pivot holes 43a so that the lever block 42 may turn about the pivot pins 42a (i.e., fulcrum). The bottom of the lever block 42 is urged against the switch 10b. Therefore, a pressing of the membrane member 41 by the finger can turn on or off the switch 10b via the lever block 42.

As shown in FIGS. 4A to 4C, as stated above, a pressing of the membrane member 41 by the finger can turn on or off the switch 10b via the lever block 42. As such, the manipulation assembly 40 may be disposed in three different configurations. For example, in FIG. 4A, a pressing of the membrane member 41 by the finger by exerting a force on a center of the membrane member 41 can horizontally dispose the lever block 42 which in turn horizontally disposes the switch 10b. In FIG. 4B, a pressing of the membrane member 41 by the finger by exerting a force to the right of the membrane member 41 can clockwise turn the lever block 42 which in turn lowers the right side of the switch 10b (i.e., inclined downward rightward). In FIG. 4C, a pressing of the membrane member 41 by the finger by exerting a force to the left of the membrane member 41 can counterclockwise turn the lever block 42 which in turn lowers the left side of the switch 10b (i.e., inclined downward leftward). Hence, the electrical outlet box can provide three options for user selection.

In addition, in an alternative embodiment a plurality of manipulation assemblies can be provided in the electrical outlet box without departing from the scope of the invention.

Alternatively, the membrane member 41 may be shaped different from that shown and disposed above the opening 30a of the cover 30 in other embodiments.

While the invention has been described in terms of preferred embodiments, those skilled in the art will recognize that the invention can be practiced with modifications within the spirit and scope of the appended claims.

What is claimed is:

1. An electrical outlet box comprising:
a housing comprising a plurality of electrical components and a switch;
a cover adapted to close onto the housing and comprising an opening above the switch; and
at least one manipulation assembly each disposed between the opening of the cover and the switch, each manipulation assembly comprising a membrane member mounted on the opening of the cover, and a lever block so that a pressing of the membrane member can turn on or off the switch via the lever block.

2. The electrical outlet box of claim 1, further comprising a separator plate disposed between the cover and the electrical components, the separator plate comprising an opening aligned with both the switch therebelow and the opening of the cover thereabove.

3. The electrical outlet box of claim 1, wherein the membrane member is flexible.
